(19) United States
(12) Patent Application Publication
(10) Pub. No.: US 2024/0243130 A1
(43) Pub. Date: Jul. 18, 2024

(54) Semiconductor Die with a Vertical Power Transistor Device

(71) Applicant: Infineon Technologies Austria AG, Villach (AT)

(72) Inventors: Andreas Peter Meiser, Sauerlach (DE); Till Schlösser, München (DE); Timothy Henson, Mount Shasta, CA (US); Thomas Martin Feil, Villach (AT)

(21) Appl. No.: 18/560,177

(22) PCT Filed: May 11, 2022
(86) PCT No.: PCT/EP2022/062803

§ 371 Date: Nov. 10, 2023

(30) Foreign Application Priority Data
May 21, 2021 (EP) EP21175158

(51) Int. Cl. H01L 27/092; H01L 21/265; H01L 21/8238; H01L 29/40; H01L 29/66; H01L 29/78

(52) U.S. Cl. CPC H01L 27/0922; H01L 21/26513; H01L 21/823828; H01L 29/407; H01L 29/66704; H01L 29/66734; H01L 29/7813; H01L 29/7825

(57) ABSTRACT

The disclosure relates to a semiconductor die (1), comprising a vertical power transistor device (2), the vertical power transistor device having a source region (3) and a drain region (4) at opposite sides of a semiconductor body (10), and a lateral transistor device (20), the lateral transistor device having a body region (221) with a lateral channel region (221.1), as well as a source and a drain region formed at a frontside of the semiconductor body, wherein a deep trench (305) is arranged laterally between the vertical power transistor device (2) and the lateral transistor device (20), forming a deep trench isolation (306).

### TECHNICAL FIELD

The present disclosure relates to a semiconductor die comprising a vertical power transistor device.

### BACKGROUND

The vertical power transistor device has a source and a drain region at opposite sides of a semiconductor body. Between, a body region with a channel region is formed, and the current flow can be controlled via a gate region next to the channel region. In addition, a drift region can be formed in the semiconductor body, e. g. vertically between the body and the drain region.

### SUMMARY

It is an object of the present application to provide an improved semiconductor die with a vertical power transistor device, as well as a method of manufacturing the same.

This object is achieved by the semiconductor die of claim 1. Moreover, it is achieved by the method of claim 14. In addition to the vertical device, the die comprises a lateral transistor device, the source and drain region of which are formed at the frontside of the semiconductor body. Laterally between the vertical device and the lateral transistor device, a deep trench isolation is formed.

The deep trench isolation can for instance allow for a reliable decoupling of the vertical and the lateral device. Since the lateral device is isolated, the backside of the die can be on another potential in the area of the lateral device compared to the vertical device, e. g. be on body potential in case of a lateral p-MOS, whereas the backside in the area of the vertical device can be on drain potential (of the vertical device). In other words, the deep trench isolation can allow for a local adjustment of a potential in the area of the lateral device, which can be advantageous in terms of a safe and stable operation.

In general words, an approach of this application is to combine a vertical power device having its source and drain region at opposite sides of the semiconductor body with a lateral device in the same die. For decoupling the lateral device from the backside potential of the vertical device, in particular the deep trench isolation can be provided in between. Alternatively or in addition, a shielding field electrode can be formed vertically between the lateral device and the backside of the die and shield the lateral device from the backside potential. Particular embodiments and features are presented throughout this disclosure and in the dependent claims. Thereby, the individual features shall be disclosed independently of a specific claim category, the disclosure relates to apparatus and device aspects, but also to method and use aspects. If for instance a device manufactured in a specific way is described, this is also a disclosure of a respective manufacturing process, and vice versa.

The deep trench can in particular surround the lateral transistor device completely, e. g. form a closed line around the lateral device seen in a top view. The lateral device can comprise a plurality of lateral device cells connected in parallel, see the exemplary embodiments for illustration. Alternatively or in addition, the semiconductor die can comprise a plurality of lateral devices, wherein each lateral device can be surrounded by a respective deep trench isolating the respective lateral device from the vertical device (and from the other lateral device or devices).

The semiconductor body, into which the deep trench or trenches is or are etched, can comprise a semiconductor substrate and for instance one or several epitaxial layers formed on the frontside of the substrate (in this epitaxial layer or layers, e. g. the source and the body and possibly the drift region of the vertical device can be formed). The deep trench forming the deep trench isolation can particularly extend down into the semiconductor substrate, e. g. intersect it completely when viewed in a vertical cross section. In other words, the deep trench can reach vertically from a frontside of the semiconductor body to a vertically opposite backside thereof.

Source and drain of the vertical device are arranged at opposite sides of the die, in particular the source region at the frontside and the drain region at the backside. The channel region of the vertical device can, in an embodiment, extend vertically, namely be arranged laterally aside a gate region formed for example in a vertical gate trench. Alternatively, the channel can extend laterally and, in consequence, be aligned vertically with the gate region, see in detail below. This lateral gate of the vertical device can in particular be combined with a vertical field electrode trench, wherein at least a portion of the lateral gate and channel region of the vertical device can be arranged above the field electrode trench, see in detail below. Providing the vertical device with a lateral gate can for instance simplify the integration of the lateral device into the same die, e. g. allow for a certain process integration (“re-use” of one or more power device process steps for the lateral device). This applies analogously, when a vertical channel of the vertical device is combined with a channel of the lateral device, formed aside a “vertical” gate electrode in a trench, see below.

“Vertical” or “vertically” refer to the vertical direction, which lies for instance perpendicular to a surface of the die, e. g. the surface of a substrate or an epitaxial layer formed on the substrate. “Above” means vertically aligned and closer to the frontside of the die, and “below” means vertically aligned and closer to the backside. “Lateral” or “laterally” refer to the lateral directions perpendicular to the vertical direction, in which for instance the die area is taken. Independently of whether the vertical or the lateral device is referred to, a respective “gate region” comprises a gate electrode and a gate dielectric, the latter capacitively coupling the gate electrode to the channel region. Likewise, a respective “field electrode region”, if provided, comprises a field electrode and a field dielectric, the latter capacitively coupling the field electrode, e. g. to a drift region of the device. The shielding field electrode, if provided, is arranged in the shielding field electrode trench, which can in particular be etched into a lower semiconductor body and be covered by an upper epitaxial layer.

In the embodiment related to the shielding field electrode region formed in a shielding field electrode trench in the semiconductor body below the lateral transistor device, at least a portion of the latter can be arranged vertically above this shielding field electrode region, e. g. at least the gate region and/or source region and/or body region and/or drain region of the lateral device. The combination of the lateral and the vertical device in the same die, wherein at least a portion of the lateral device is arranged above a shielding field electrode region, shall also be disclosed independently of the deep trench isolation formed between the devices.

The shielding field electrode can for instance reduce the electrical potential between a backside of the die and the frontside with the lateral device, e. g. reduce the backside drain potential. This can allow for a safe and stable operation of the lateral device, wherein for example a die with a common drain backside for the vertical power device is possible. Generally, also independently of the shielding field electrode region below, the integrated lateral device, monolithically in the same die, can for instance be used to optimize the operational performance of the vertical power device, e. g. by connecting the lateral transistor as a pull-down FET. It can be used as a gate driver for the vertical device, e. g. a first lateral device for charging the gate and a second lateral device for discharging the gate. The first device can be an p-MOS, and the second device an n-MOS.

In an embodiment, a well region is formed laterally aside the shielding field electrode trench and is doped with an opposite conductivity type as the source and drain region of the vertical power device. The well region can in particular be electrically connected to the source region of the vertical device, it can reduce or compensate the backside potential, in particular the drain potential of the power device. Above the well region, at least a portion of the lateral transistor device can be arranged, e. g. its source or drain region, the other region being arranged above the shielding field electrode region. If the body region of the lateral device is made of the same doping type like the well region, e. g. p-type, these two regions can for instance differ in their doping concentration.

Seen in a vertical cross-section, the well region can be formed laterally between two neighbouring shielding field electrode regions, e. g. extend from the sidewall of one shielding field electrode trench to a sidewall of the other trench. The lower end of the well region can for instance be arranged at a larger vertical height (closer to the frontside) than a lower end of the neighbouring trench or trenches. Vertically below the well region, e. g. still between the trenches, the semiconductor body can be doped with the same charge carrier type as in the source and the drain region of the vertical device. With a respective additional implant region below the well, the potential or electrical field can decline over the vertical extension of the additional implant and well region upwards, resulting for example in a basically field-free situation at its upper end. In the exemplary embodiments, power source and drain are n-doped, the well region is a p-well, and the additional implant region is n-doped.

In an embodiment, a field electrode trench, in which a field electrode of the vertical power device is formed, and the shielding field electrode trench have a different vertical depth and/or different lateral width. The shielding field electrode trench can for instance be deeper and/or wider than the power device trench, in particular both. The width can for example be taken in a lateral direction which defines a translational symmetry for cells of the power device. The trenches of the power device and those below the lateral transistor device can be etched in a common process step, wherein for instance a wider opening in an etch mask, which defines a wider trench, can also relate to a deeper trench due to the better etch attack. A wider and/or deeper trench below the lateral device can for instance reduce or compensate a higher backside potential (e. g. assuming the same pitch), whereas a narrow trench of the vertical power device can be advantageous in terms of the area use and die size. Alternatively, however, the field electrode trenches of the vertical and lateral device can also have the same width and depth, e. g. be etched in the same etch step with the same mask opening.

In an embodiment, a bridge implant region is formed below the drift region of the vertical power device, made of the same conductivity type but with a higher dopant concentration than the drift region. The concentration can for instance lie between the drift and the drain region, e. g. close to the latter. With the bridge implant region, the drain region formed at the backside of the die can be lifted, which can avoid an Rₒₙ·A increase. A thicker semiconductor body, in particular thicker lower epitaxial layer (see below), can for instance be advantageous in view of wider/deeper trenches below the lateral device. The bridge implant region can for instance be formed only below the vertical device, but not below the lateral device. Due to the bridge implant region, the lower end of the drift region of the vertical device can lie on a larger vertical height (closer to the frontside) than a lower end of region below the lateral device, which is formed with the same doping type and concentration like the drift region.

In an embodiment, a contact region of the shielding field electrode extends to a lateral position aside the channel region of the lateral device. From there, it can extend vertically upwards, e. g. up to the frontside of the semiconductor body, allowing for an electrical connection of the shielding field electrode. The electrical connection can for instance avoid a floating region inside the semiconductor body. The shielding field electrode can for instance be on source potential of the lateral device, and the contact region can be routed upwards aside its source contact. Seen in a vertical cross section, the sectional plane lying for instance in parallel to the channel region of the lateral device, a first portion of the shielding field electrode can extend below the gate electrode of the lateral device, wherein the contact region extends further sidewards than the gate electrode and is routed upwards aside the gate electrode. The contact region can in particular be made of the same conductive material as the first portion of the shielding field electrode, e. g. of polysilicon. In general, however, the shielding field electrode of the lateral device is not necessarily connected but can be floating (e. g. due to the decoupling by the deep trench isolation).

In an embodiment, a gate electrode of the lateral device is arranged in a trench laterally aside the channel region of the lateral device. The channel region extends laterally between source and drain arranged at the frontside of the semiconductor body, but the gate electrode is not arranged above, instead it is arranged aside the channel in the trench. In other words, a gate type usually used for vertical devices is used for the lateral device. This embodiment can in particular be combined with a vertical device comprising a gate electrode in a trench with the channel region laterally aside. In contrast to the lateral device, in terms of the current flow, the channel region of the vertical device extends vertically between source and drain formed at the frontside and backside of the semiconductor body. In this way, the same type of gate electrodes, which can for instance be manufactured simultaneously in the same process steps, can be used differently for the vertical and the lateral device. Also the trenches, in which the gate electrodes of the vertical and the lateral device are respectively arranged, can be etched simultaneously.

In general, the gate electrode and a field electrode of the vertical device can be arranged in separate trenches aside each other. In particular, however, the field electrode of the vertical device can be arranged in the same trench below the gate electrode, the gate electrode capacitively coupling to the channel region and the field electrode capacitively coupling to the drift region below the body/channel region. Seen in a vertical cross-section, the field and gate electrode of the vertical device can be electrically isolated by a dielectric material, e. g. silicon oxide.

Referring to the lateral device with the gate electrode in the trench, the portion of the trench below the gate electrode can be completely filled with a dielectric material, e. g. silicon oxide, no shielding field electrode being provided in the lower portion of the trench. This applies even in case of a trench having basically the same depth as a trench of the vertical device containing a field electrode, because the lower portion of the trench of the lateral device can for instance be filled with a thick bottom oxide. In a particular embodiment, however, the shielding field electrode of the lateral device is arranged below its gate electrode in the trench. The trench can extend from the frontside of the semiconductor body into the latter, the gate electrode being arranged in an upper portion of the trench (at the frontside) and the shielding field electrode being arranged in a lower portion thereof (at a larger distance from the frontside).

Seen in a vertical cross-section, the sectional plane lying for instance parallel to a first lateral direction, the gate electrode of the lateral device can be electrically isolated from the shielding field electrode by a layer of dielectric material, e. g. silicon oxide. In a second lateral direction perpendicular to the first lateral direction, the trench can for instance have a longitudinal extension, forming for instance a stripe seen in a vertical top view. In the first lateral direction, a plurality stripes can for example be arranged aside each other. Generally, the gate electrode of the lateral device and the shielding field electrode can have basically the same extension in the second lateral direction, e. g. lie basically flush in the vertical direction (for instance in case of a floating shield electrode, see above). In particular, however, a contact region of the shielding field electrode can extend further sidewards than the gate electrode, see in detail above.

In an embodiment relating to the gate electrode of the lateral device formed in the trench, a counterdoping layer is disposed laterally between the body region of the lateral device and its gate region. Seen in a vertical cross section, the sectional plane lying for instance parallel to the first lateral direction (see above), the counterdoping layer is enclosed laterally between channel region, and the gate dielectric of the lateral device. This gate dielectric is formed at the sidewall of the trench, it capacitively couples the gate electrode to the channel region of the lateral device. The counterdoping layer is formed in the semiconductor body adjacent this sidewall of the trench. In the first lateral direction, in which the thickness of the counterdoping layer is taken, its extension is smaller than in the vertical direction, the thickness can for instance be not more than 50%, 30% or 20% of the vertical extension (a possible lower limit can for instance be 1%). In absolute values, the thickness of the counterdoping layer can for instance be not more than 100 nm, a possible lower limit being for example 10 nm.

Independently of the geometric details, the counterdoping layer is made of an opposite conductivity type compared to the body region of the lateral device. In other words, in case of a body region made of a first conductivity type, the counterdoping layer is made of an opposite second conductivity type. In case that the lateral device is a p-MOS, its body region is n-doped and the counterdoping layer is p-doped. The comparably thin depletable counterdoping layer at the surface of the channel region can allow for an adaption of the threshold voltage, e. g. reduce the threshold voltage that could be too high in case of the n-channel p-MOS.

The body region of the lateral device and/or in particular the thin counterdoping layer can for instance be formed by an implantation through the sidewall of the trench. In this or these implantation step(s), the gate electrode is not formed yet in the upper portion of the trench, and the dopant species can be implanted obliquely through the sidewall of the trench into the semiconductor body. In this way, in particular the thin counterdoping layer with the vertical extension can be formed. As a consequence of the oblique implantation of the body region and/or counterdoping region, a residual doping region can extend from below the channel region obliquely away from the channel region downwards, it can for instance have a drop shape seen in the sectional plane parallel to the first lateral direction.

In an embodiment, the channel region of the lateral device is offset downwards into the semiconductor body. Seen in a sectional plane parallel to the first lateral direction, an upper end of the lateral channel region can be arranged on a vertical height below the frontside of the semiconductor body. In a particular embodiment, a surface channel blocker region can be formed above the channel region of the lateral device, it can for instance cover the body region as a whole vertically upwards. The channel blocker region is made of the same conductivity type as the body region but with a higher dopant concentration, resulting in a local increase of the threshold voltage. In this way, the threshold voltage can locally be set to a value above the maximum gate voltage, and a reduced or uncontrolled threshold voltage at the upper edge can be avoided. In case of the p-MOS, the channel blocker region is highly n-doped (compared to the body region with a lower n-doping).

In an embodiment, the lateral device comprises a lateral drift region, which is formed between the lateral channel and the drain region. It is made of the same conductivity type as the drain region of the lateral device, but with a lower doping concentration. If the lateral device is a p-MOS, its drift region can be p-doped. For a field shaping, an electrode can capacitively couple to the drift region of the lateral device via a lateral field dielectric. In an embodiment, this lateral field dielectric is thicker than a lateral gate dielectric capacitively coupling the gate electrode of the lateral device to its channel region.

In general, one single electrode can form the lateral gate electrode and the lateral field electrode, so that the latter is on gate potential and for instance coupled via a thicker field dielectric to the drift region (see above). In a particular embodiment, however, the lateral field electrode is electrically isolated from the lateral gate electrode. Depending on the application, the lateral field electrode can for instance be connected to the source region of the lateral device, or it can be controlled separately.

In an embodiment, the lateral field electrode is arranged laterally aside the drift region of the lateral device, namely in a trench. In particular, it can be arranged in the same trench as the gate electrode of the lateral device, the gate and the field electrode arranged aside each other with respect to a second lateral direction. In the lateral portion of the trench, in which the lateral field electrode is formed, a thicker dielectric layer compared to the portion with the lateral gate electrode can be formed. The lateral field electrode can be connected to the shield electrode formed below the lateral gate electrode, e. g. made of the same conductive material (for instance polysilicon). Then, a contact to the shield electrode and, in consequence to the lateral field electrode, can be formed via a contact region of the shield electrode, see above. Seen in a vertical cross-section parallel to the second lateral direction, the conductive material can form a U-shape, the first portion of the shielding field electrode extending below the lateral gate electrode, the contact region extending upwards on one side of the lateral gate electrode, and the lateral field electrode extending upwards on the other side thereof. Depending on the requirements of the specific lateral device, the length of the lateral field electrode, which is taken in the second lateral direction, can be adapted by layout measures, and the integration of the lateral gate and field electrode can allow for a reuse of process steps.

In an embodiment, a source and/or a drain contact of the lateral transistor device extends through an insulating layer formed on the semiconductor body, e. g. a silicon oxide or borophosphosilicate glass (BPSG) layer. The contact or contacts intersect the insulating layer, connecting the respective region for instance to a wiring or metallization layer formed above. The contact or contacts are made of an electrically conductive material, in particular metal, for instance tungsten. To improve the connection to the respective region, e. g. an n+- or p+-implantation can be introduced adjacent to the contact (n+ in an n-region, and p+ in a p-region), for example via a respective mask.

In an embodiment, a first one of the contacts is arranged vertically above the shielding field electrode region and/or a second one of the contacts is arranged on a lateral position between two shielding field electrode trenches. Seen in a vertical cross-section, in particular a symmetrical design is possible, e. g. with one second contact centrally and two first contacts above the two shielding field electrode regions (one first contact above each region).

Independently of these details, the first contact arranged above the shielding field electrode region can in particular be arranged vertically above the shielding field electrode, e. g. centrally above the shielding field electrode trench. Generally, an insulating spacer can be formed in the shielding field electrode trench, covering the electrode upwards. The first contact can extend through the insulating spacer. Seen in a vertical cross-section, it can end above the insulating spacer, e. g. inside the body region, which can enable a good contact formation at the bottom of the contact. Alternatively, the contact can extend down to the insulating spacer, ending for instance on the latter, namely at an upper end of the insulating spacer. As a further alternative, the contact can extend into the spacer but end above the field electrode. In any of these cases, the field electrode and the contact are, seen in a vertical cross-section, electrically isolated from each other. This can for instance decouple switching events of the vertical power device from the lateral transistor device. Depending on the specific design, the first can be a source contact and the second one a drain contact, or the first contact can be a drain contact and the second one a source contact. This applies for both, independently of whether an n-MOS or a p-MOS is formed.

In an embodiment, the well region discussed above is electrically connected to the source contact or to the drain contact of the lateral device. In other words, in particular, the source or the drain region of the lateral device can be electrically connected to the source region of the vertical power device.

In an embodiment, the source and/or drain region of the lateral device comprises a surface implant with a doping concentration which is higher than the doping concentration of the body region of the vertical device. In particular, the body region of the vertical device can be p-doped, and a higher p-doping can be implanted into the lateral source and/or drain region (which are p-type in case of a p-MOS). The surface implant can in particular be formed directly at the frontside of the semiconductor body, e. g. as a p⁺ implant close to the surface increasing the performance of the p-MOS.

In an embodiment, a source contact of the lateral device extends vertically through the source region down into the body region of the lateral device. In other words, the source contact intersects the source region vertically and additionally forms a body contact below. This combined use of the vertical interconnect can allow for a space saving layout, e. g. without a separate body contact aside. The body region of the lateral device can extend laterally to a location below the lateral source region. A lower end of the lateral source region can be arranged at a larger vertical height (closer to the frontside) than a lower end of the lateral drain region, the latter can have a larger vertical extension than the lateral source region. Consequently, the vertical contact extending through the lateral source region can be formed in the same process step with the vertical contact of the lateral drain region. The vertical contacts can have the same vertical extension and lie on the same vertical height.

In an embodiment, the shielding field electrode trench extends from a frontside of a lower semiconductor body into the latter, wherein an upper epitaxial layer is formed on the frontside of the lower semiconductor body. The lower semiconductor body can for instance comprise a semiconductor substrate and a lower epitaxial layer deposited onto the substrate, in which for instance a drift region of the vertical device can be formed. In the area of the lateral device, e. g. the well region, in particular the p-well, can be formed in the lower epitaxial layer. Optionally, the additional implant region can be formed below the well region. The different doping of the lower epitaxial layer in the areas of the vertical and the lateral device can for instance be achieved with a respective masking in an implantation subsequent to the epitaxial deposition of the layer (e. g. in combination with an in situ doping during the deposition or as an alternative).

The trench or trenches, in particular the shielding field electrode trench for the lateral device and field electrode trenches for the vertical device, are etched into the lower semiconductor body, in particular into the lower epitaxial layer. The trench or trenches can in particular extend solely in the lower semiconductor body, particularly solely in the lower epitaxial layer. After forming the field electrode regions, the upper epitaxial layer can be deposited onto the frontside of the lower semiconductor body, in particular onto the lower epitaxial layer.

In the upper epitaxial layer, e. g. above the shielding field electrode trench and the well region, the lateral device can be formed. In particular, the source, body and drain region of the lateral device can be formed by respective implantations in the upper epitaxial layer. The lateral gate region can be formed subsequently on the upper epitaxial layer, e. g. by depositing and structuring a field dielectric layer and depositing and structuring a field electrode layer. In case of a lateral device with a lateral drift region (see above), a thicker dielectric and/or separate field electrode can be formed above).

In an embodiment, the vertical power device comprises a lateral channel and gate region, wherein the former can in particular be formed in the upper epitaxial layer. Due to the lateral design, the gate and the channel region are vertically aligned, in particular the gate region above the channel region. Particularly, at least a portion of the lateral channel and gate region can be arranged above a field electrode region of the vertical device, seen in a vertical cross-section e. g. a portion of at least 30%, 50%, 70% or 90%, in particular the whole channel region can be vertically aligned with the field electrode region. As illustrated in the exemplary embodiments in detail, the vertical device can in particular comprise a first gate region formed above a first side of the field electrode region or trench, and it can comprise a second gate region formed above a second side thereof, the first side lying at a first sidewall and the second side lying at a laterally opposite second sidewall of the field electrode trench of the vertical device, seen in a vertical cross-section.

Generally, the lateral channel and gate region of the vertical device, and in particular the at least proportional arrangement above the field electrode trench, can allow for an efficient area use.

With a vertical channel, which can be an alternative in general, the possibilities for a further lateral shrink can be limited, e. g. because the field electrode trench itself requires a certain lateral width. This limitation can be circumvented at least to some extent by arranging the channel region of the vertical power device above the field electrode trench. Providing not only the lateral but also the vertical transistor device with a lateral gate region can also allow for a certain process integration, e. g. a simultaneous formation of the gate dielectrics and/or the gate electrodes of the vertical and the lateral device.

In an embodiment, a second lateral transistor device is formed in the semiconductor die in addition to the first lateral transistor device. Like the latter, the second lateral device can be formed above a shielding field electrode region and/or a well region. Generally, any embodiment described for the first lateral device shall also be disclosed for the second lateral device. In particular, the first and the second lateral device can be of an opposite majority charge carrier type, one being a p-MOS and the other one being an n-MOS. These devices can for instance be connected as a CMOS structure, allowing e. g. the integration of a certain logic function. To form for instance an inverter, the gate regions of the two devices can be connected as an input, and their drain regions as an output.

As mentioned, the application relates also to a method of manufacturing the semiconductor die disclosed here. It can comprise the steps:
i.) etching and filling the deep trench;
ii.) forming the vertical power device;
iii.) forming the lateral transistor device.

The steps ii) and iii) can, at least to some extent, be performed simultaneously, see the remarks to the “re-use” of existing process steps. For instance, the trenches, in which the vertical and the lateral gate electrode are arranged, can be etched simultaneously. Alternatively or in addition, the gate electrodes of the lateral and the vertical device can be formed simultaneously. A shield electrode below the lateral device can, if provided, be formed simultaneously with the field electrode of the vertical device. The lateral field electrode of the lateral device can, if provided, be formed simultaneously with the gate electrode or electrodes of the vertical and/or lateral device.

Alternatively or in addition, implantation steps can be re-used, e. g. by simultaneously forming the lateral source/drain regions and the vertical body region, and/or by simultaneously forming the lateral body region and the vertical source region. In case of a lateral n-MOS, however, the p-body implantation of the vertical device might possibly be not homogeneous enough for the lateral n-channel, and the vertical p-body and lateral p-body can also be formed in separate process steps. Alternatively or in addition, electrical contacts can be formed simultaneously, e. g. the vertical interconnects for the lateral source and/or drain region and a vertical source contact for the vertical device.

In a particular embodiment relating to the lateral device having its gate electrode in a trench, the lateral body and/or counterdoping region is formed prior to the deposition of the gate electrode by implanting the respective dopant obliquely through the sidewall of the trench into the semiconductor body. In this process step, the upper portion of the trench, in which the lateral gate electrode is arranged later on, is not filled yet, and the dopant species can be implanted through this upper portion via the sidewall into the semiconductor material. “Obliquely” means neither vertical nor parallel to the vertical direction. The oblique implantation can allow for the formation of comparably thin regions/layers aside the trench sidewall and, consequently, aside the gate region later on. In particular, it can allow for the integration of the thin counterdoping layer, see above. During the oblique implantation, the trench or trenches of the vertical device, which can for instance have been etched and partially filled simultaneously with the trench of the lateral device before, can be protected by an etch mask.

Alternatively or in addition, the method can comprise the steps:
i) etching the shielding field electrode trench;
ii) forming the shielding field electrode region with the shielding field electrode, and, subsequently,
iii) forming the lateral transistor device.

As discussed above, a lateral device with a shielding field electrode below shall also be disclosed independently of the deep trench isolation and can particularly be summarized by the following aspects:
1. aspect: A semiconductor die (1), comprising
   a vertical power transistor device (2),
      the vertical power transistor device (2) having a source region (3) and
      a drain region (4) at opposite sides (10a,b) of a semiconductor body (10), and
   a lateral transistor device (20),
      the lateral transistor device (20) having a body region (21) with a lateral
      channel region (21.1), as well as a source and a drain region (23, 24)
      formed at a frontside (10a) of the semiconductor body (10),
wherein a shielding field electrode region (30) with a shielding field electrode (31) is formed in a shielding field electrode trench (32) in the semiconductor body (10), and wherein at least a portion of the lateral transistor device (20) is arranged vertically above the shielding field electrode region (30).
2. aspect: The semiconductor die (1) of aspect 1, wherein a well region (35) is formed in the semiconductor body (10) laterally aside the shielding field electrode trench (32), the well region (35) doped with an opposite conductivity type as the source and the drain region (3, 4) of the vertical power transistor device (2) and electrically connected to the source region (3) of the vertical power transistor device (2).
3. aspect: The semiconductor die (1) of aspect 1 or 2, the vertical power transistor device (2) comprising a field electrode region (5) with a field electrode (7) formed in a field electrode trench (6), wherein the field electrode trench (6) of the vertical power transistor device (2) and the shielding field electrode trench (32) differ from each other in at least one of their respective vertical depth and their respective lateral width.
4. aspect: The semiconductor die (1) of any one of the preceding aspects, the semiconductor body (10) comprising a semiconductor substrate (10.1) and a lower epitaxial layer (10.2), wherein a drift region (9) of the vertical power transistor device (2) is formed in the lower epitaxial layer (10.2), and wherein a bridge implant region (11) is formed at a lower end of the lower epitaxial layer (10.2), the bridge implant region (11) made of the same conductivity type as the drift region (9) but with a higher doping concentration than the latter.
5. aspect: The semiconductor die (1) of any one of the preceding aspects, wherein the lateral transistor device (20) comprises a lateral drift region (40), which is arranged laterally between the lateral channel region (21.1) and the drain region (24) of the lateral transistor device (20), the drift region (40) made of the same conductivity as the drain region (24) with a lower doping concentration than the latter.
6. aspect: The semiconductor die (1) of aspect 5, wherein a lateral field dielectric (47) formed vertically above the lateral drift region (40) has a greater vertical thickness than a lateral gate dielectric (46) formed vertically above the channel region (21.1).
7. aspect: The semiconductor die (1) of aspect 6, wherein a lateral field electrode (50) is formed above the lateral field dielectric (47), the lateral field electrode (50) being electrically isolated from a lateral gate electrode (45) formed vertically above the lateral gate dielectric (46).
8. aspect: The semiconductor die (1) of any one of the preceding aspects, an insulating layer (55) formed on the semiconductor body (10), wherein a source contact (26) electrically contacting the source region (23) of the lateral transistor device (20) and a drain contact (27) electrically contacting the drain region (24) of the lateral transistor device (20) extend through the insulating layer (55), wherein a first one of the contacts (26,27) is arranged vertically above the shielding field electrode region (30).
9. aspect: The semiconductor die (1) of aspect 8, an insulating spacer (37) being formed vertically above the shielding field electrode (31) in the shielding field electrode trench (32), wherein the first contact extends to the insulating spacer (37).
10. aspect: The semiconductor die (1) of aspect 8 or 9, wherein a second one of the contacts (26,27) is arranged on a lateral position between the shielding field electrode trench (32) and an additional shielding field electrode trench (32).
11. aspect: The semiconductor die (1) of aspect 2 in combination with any one of aspects 8 to 10, wherein the well region (35) is electrically connected to the source contact (26) or the drain contact (27) of the lateral transistor device (20).
12. aspect: The semiconductor die (1) of any one of the preceding aspects, wherein the shielding field electrode region (30) is formed in a lower semiconductor body (10.1,10.2), the shielding field electrode trench (32) extending from a frontside of the lower semiconductor body (10.1,10.2) into the latter, wherein the source, the body and the drain region (21,23,24) of the lateral transistor device (20) are formed in an upper epitaxial layer (10.3) deposited onto the lower semiconductor body (10.1,10.2).
13. aspect: The semiconductor die (1) of aspect 12, wherein the source region (3) and a channel region of the vertical power transistor device (2) are formed in the upper epitaxial layer (10.3).
14. aspect: The semiconductor die (1) of any one of the preceding aspects, in which an additional lateral transistor device (70) is formed, the lateral transistor devices (20,70) being of an opposite majority charge carrier type and being electrically connected as a CMOS structure.
15. aspect: A method of manufacturing the semiconductor die (1) of any one of the preceding aspects, comprising the steps:
   i) etching (96) the shielding field electrode trench (32);
   ii) forming (97) the shielding field electrode region (30) with the shielding field electrode (31), and, subsequently,
   iii) forming (99) the lateral transistor device (20).

Regarding further possible details, reference is made to the description above and to the exemplary embodiments. In particular, in step i), the field electrode trench of the vertical device can be etched simultaneously. Alternatively or in addition, when in step iii) the lateral gate region of the lateral device is formed, a lateral gate region of the vertical device can be formed simultaneously, see above.

### BRIEF DESCRIPTION OF THE DRAWINGS

Below, the semiconductor die with the vertical and lateral devices and the manufacturing are explained in further detail by means of exemplary embodiments. Therein, the individual features can also be relevant in a different combination.

FIG. 1 shows a portion of a semiconductor die with vertical and lateral devices;

FIG. 2a shows a vertical top view of the lateral device surrounded by a deep trench isolation;

FIG. 2b shows a cross-section of the embodiment of FIG. 2a;

FIG. 3a shows an alternative lateral device with additional features in a vertical top view;

FIG. 3b shows the embodiment of FIG. 3a in a cross-sectional view;

FIG. 4 shows an alternative lateral device in a cross-sectional view;

FIG. 5 shows another lateral device in a vertical top view;

FIGS. 6a-d illustrate some manufacturing steps and further features of the lateral device;

FIG. 7 shows a flow diagram summarizing some manufacturing steps;

FIG. 8 shows a portion of a semiconductor die with vertical and lateral devices;

FIG. 9 shows a first design of a lateral device in a detailed view;

FIG. 10 shows a second design of a lateral device in a detailed view;

FIG. 11 shows a third design of a lateral device in a detailed view;

FIG. 12 shows a fourth design of a lateral device in a detailed view;

FIG. 13 illustrates two lateral devices in a CMOS structure;

FIG. 14a-d illustrate some manufacturing steps;

FIG. 15 summarizes some manufacturing steps in a flow diagram.

### DETAILED DESCRIPTION

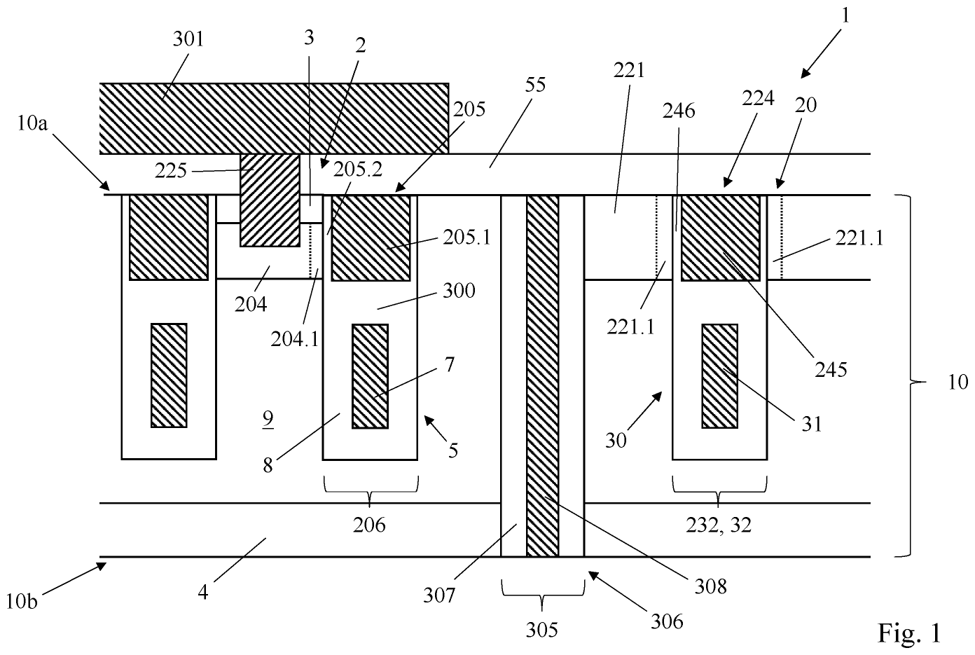

FIG. 1 shows a semiconductor die 1 with a vertical power transistor device 2. It has a source region 3 formed at a frontside 10a and a drain region 4 formed at a backside 10b of a semiconductor body 10. In a body region 204, a channel region 204.1 is formed laterally aside a gate region 205, which is arranged in a gate electrode trench 206. The gate electrode region 205 comprises a gate electrode 205.1 and a gate dielectric 205.2 capacitively coupling the gate electrode 205.1 to the channel region 204.1. Between the body and the drain region 204.4, a drift region 9 is arranged.

Below the gate electrode 205.1, in the same gate electrode trench 206, a field electrode 7 is formed. Via a field dielectric 8, it capacitively couples to the drift region 9. The field electrode 7 and the gate electrode 205.1 are electrically isolated from each other by a dielectric spacer 300. A source and body contact 225 of the vertical device 2 connects the source and body region 3, 204 to a frontside metallization 301 formed above. The contact 225 intersects an insulating layer 55 on the frontside 10a of the semiconductor body 10.

In addition to the vertical device 2, a lateral transistor device 20 is formed in the die 1. It comprises a source and a drain region lying in front of and behind the sectional plane of FIG. 1, see the figures below for illustration. Like the source and the drain region, a body region 221 of the lateral device 20 is arranged at the frontside 10a of the semiconductor body 10. In the body region 221, a channel region 221.1 is formed laterally aside a lateral gate region 244, which comprises a gate dielectric 246 and a gate electrode 245 formed in a trench 232. The trench 232 is etched and filled simultaneously with the trench 206 of the vertical device 2. In the same process step with the field electrode 7 in the trench 206, a shielding field electrode 31 is formed in the trench 232, and the gate electrodes 205.1, 245 of the vertical and lateral device 2, 20 can be formed simultaneously as well.

Although they are formed in the same die 1, the vertical and lateral device 2, 20 are electrically isolated from each other by a deep trench 305 forming a deep trench isolation 306. The deep trench 305 intersects the semiconductor body 10 completely, it extends from the frontside 10a to the backside 10b. In detail, the deep trench 305 is filled with a dielectric material 307 covering the sidewalls and a conductive material 304, e. g. polysilicon, filling a central portion of the trench 305.

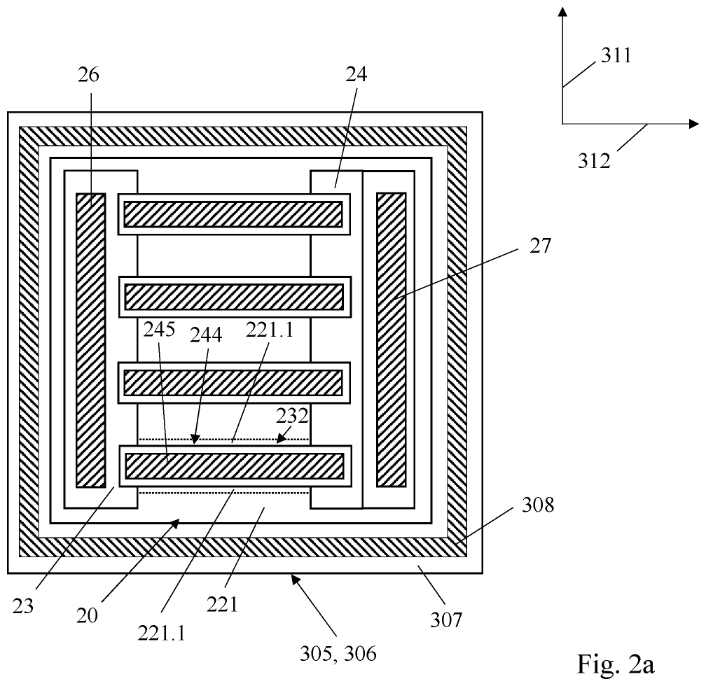

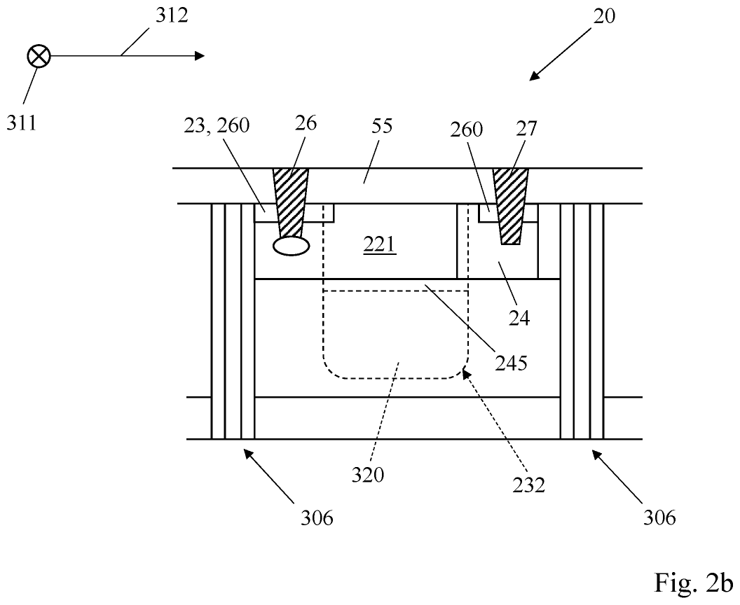

FIG. 2a shows the lateral device 20 in a vertical top view. It is completely surrounded by the deep trench 305. The sectional plane of FIG. 1 lies parallel to a first lateral direction 311 (and to the vertical direction), in a second lateral direction 312 the trench 232 has a longitudinal extension. The lateral gate region 244 with the gate electrode 245 has a longitudinal extension as well, forming a stripe. In detail, the lateral device 20 comprises a plurality of stripe-shaped device cells (four stripes are exemplary shown in FIG. 2a).

The trench 232 extends between a source region 23 and a drain region 24 of lateral device 20. In the body region 221 the channel regions 221.1 are formed on both sides of the trench 232. From above, the source region 23 is contacted via a source contact 26 and the drain region 24 is contacted via a drain contact 27, which intersect the insulating layer 55 (see FIG. 1 for comparison).

FIG. 2b shows the lateral device 20 of FIG. 2a in a vertical cross-section, the sectional plane lying parallel to the second lateral direction 312. Generally, in this disclosure, the same terms or reference numerals are used to indicate the same features or features having the same function, and reference is also made to the description of the respectively other figures. As apparent from the cross-section, the source region 23 has a smaller vertical extension than the drain region 24, and the body region 221 reaches below the source region 23. The source contact 26 intersects the source region 23 vertically and forms a body contact in addition. In this example, the body region 221 is p-doped and the source and the drain regions 23, 24 are n-doped. The source and the drain region 23, 24 comprises a respective high dose surface implant 260 (n⁺ in this case).

The trench 232 with the gate electrode 245 lies behind the drawing plane, the sectional plane lies between two stripes of FIG. 2a. In the embodiment shown here, in contrast to FIG. 1, no shield electrode is arranged below the gate electrode 245, even though the trench 232 has the same depth as the gate electrode trench 206 of the vertical device 2. A thick bottom oxide 320 fills the lower portion of the trench 232 in FIG. 2b.

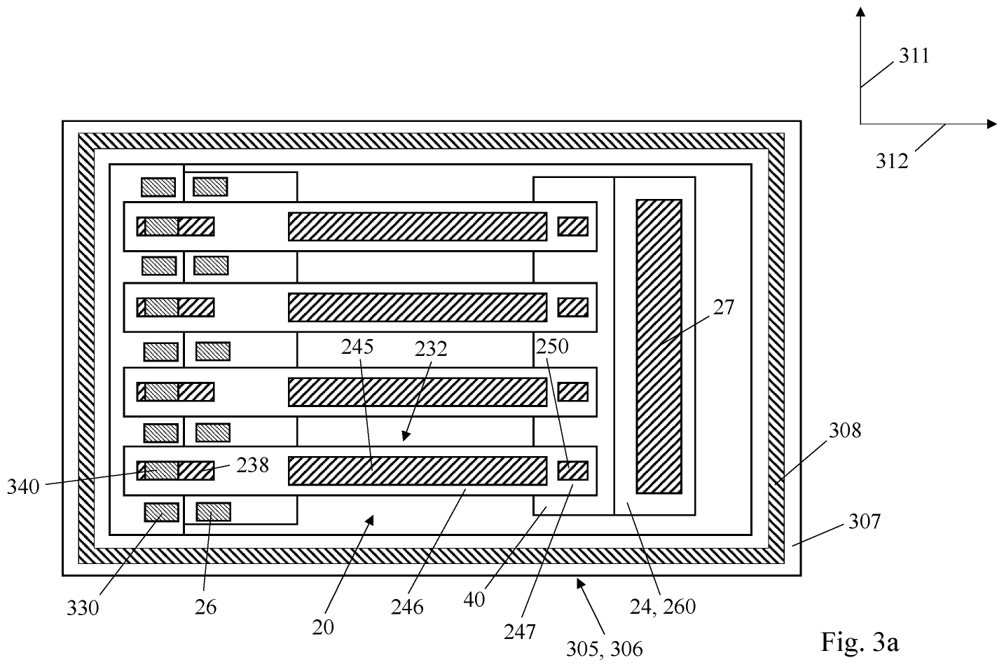

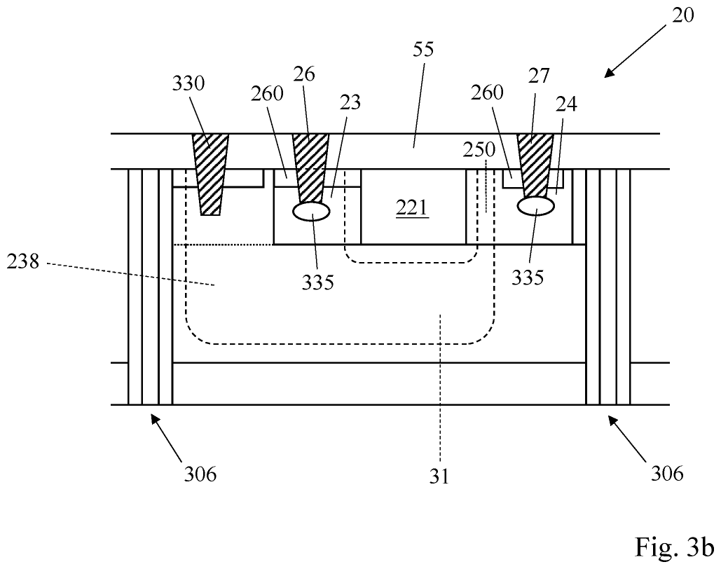

FIG. 3a shows an alternative embodiment of the lateral device 20 in a vertical top view, wherein the following description also relates to the sectional view of FIG. 3b. In addition to the gate electrode 245, a lateral field electrode 250 is formed in the trench 232. It capacitively couples to a drift region 40 of the lateral device, which has the same doping but a lower doping concentration compared to the drain region 24. The lateral field electrode 250 capacitively couples to the drift region 40 via a lateral field dielectric 247 which is thicker than the lateral gate dielectric 246. The lateral gate electrode 245 and the lateral field electrode 250 are arranged aside each other with respect to the second lateral direction 312. Depending on the requirements, the length of the drift region 40 and of the lateral field electrode 250 can be adapted by layout measures.

In the source and the drain region 23, 25, a respective surface implant 260 is formed. In the example shown, these are p⁺-implants having a higher doping concentration compared to the body region 204 of the vertical device 2. In contrast to FIG. 2b, the source region 23 has the same vertical extension as the drain region 24. In the embodiment of FIG. 3b, a separate contact 330 is provided for contacting the body region 221. The body region 221 extends laterally below the source region 23 to the contact 330. At the contacts 26, 27, a respective high dose implant region 335 is formed at the lower end, which is a respective p⁺-implant in this example showing a p-MOS.

As can be seen in FIG. 3a, a further vertical contact 340 contacts a contact region 238 of the shielding field electrode 31 formed below the gate electrode 245, see the dashed lines in FIG. 3b for comparison. The conductive material forming the shielding field electrode 31, polysilicon in this case, forms a U-shape in the trench 232. A horizontal portion forms the shielding field electrode 31, wherein a first vertical portion is arranged at one lateral end and forms the contact region 238, and a second vertical portion is arranged at the laterally opposite end and forms the lateral field electrode 250.

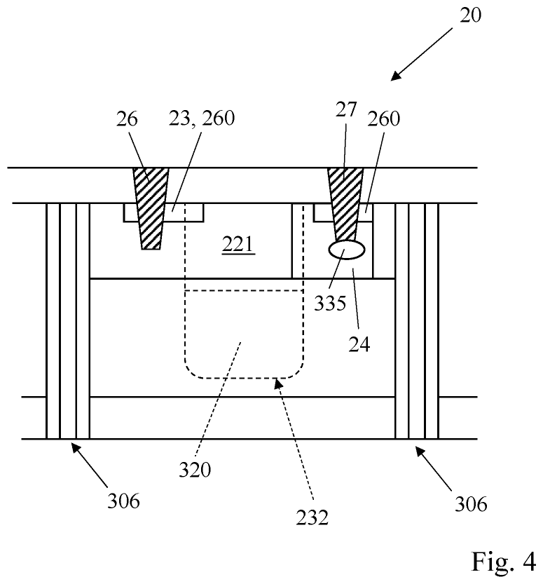

FIG. 4 illustrates a lateral device 20, which is basically comparable to the one of FIG. 2b. In the trench 232, a thick bottom oxide 320 is formed below the gate electrode, and the source contact 26 intersects the source region 23/surface implant 260 and forms a body contact below. However, in contrast to FIGS. 2a, b, the device 20 of FIG. 4 is a p-MOS, the source region 23 and the drain region 24 are p-doped, the body region 221 being n-doped.

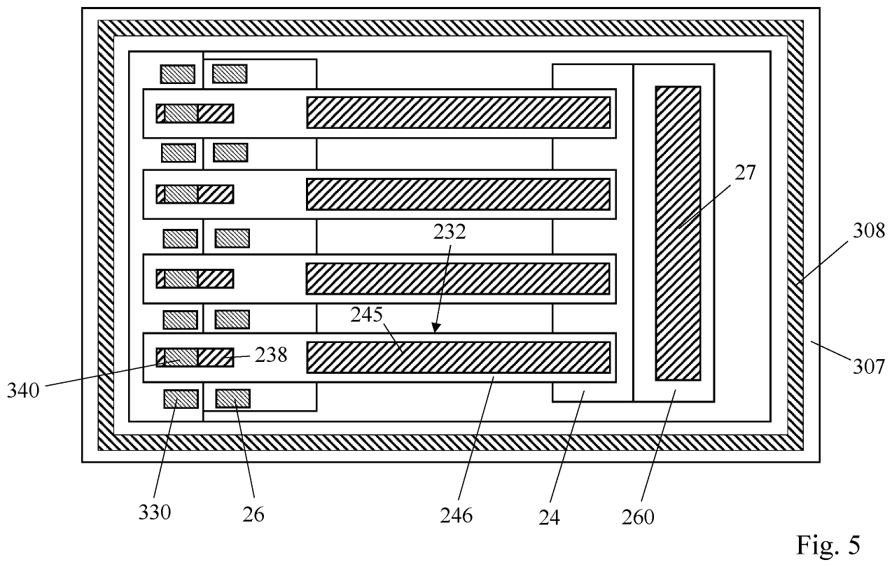

FIG. 5 shows a lateral device 20 having a comparable setup as the one of FIGS. 3a, b. In particular, a contact region 238 of the shield electrode (not visible in FIG. 5) formed below the lateral gate electrode 245 extends laterally aside and upwards, the shield electrode is contacted by the contact 340. Moreover, a separate contact 330 for contacting the body region 221 is provided. However, in contrast to the embodiment of FIGS. 3a, b, no lateral field electrode is formed in the trench 232 aside the gate electrode 245.

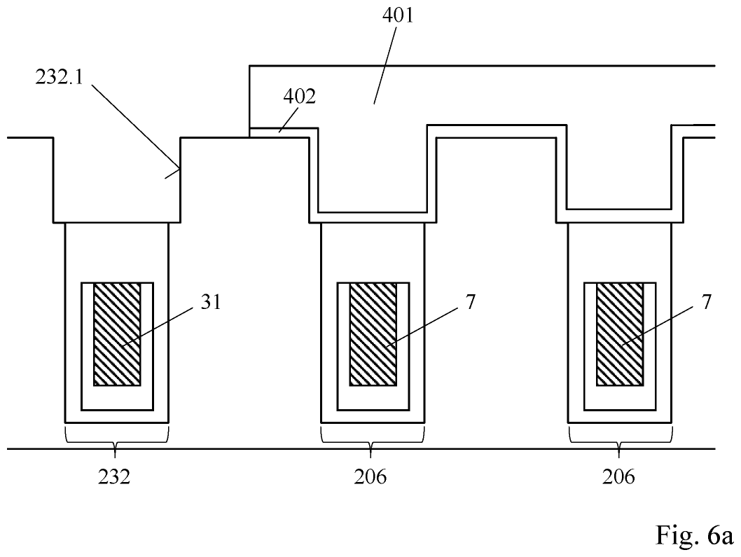

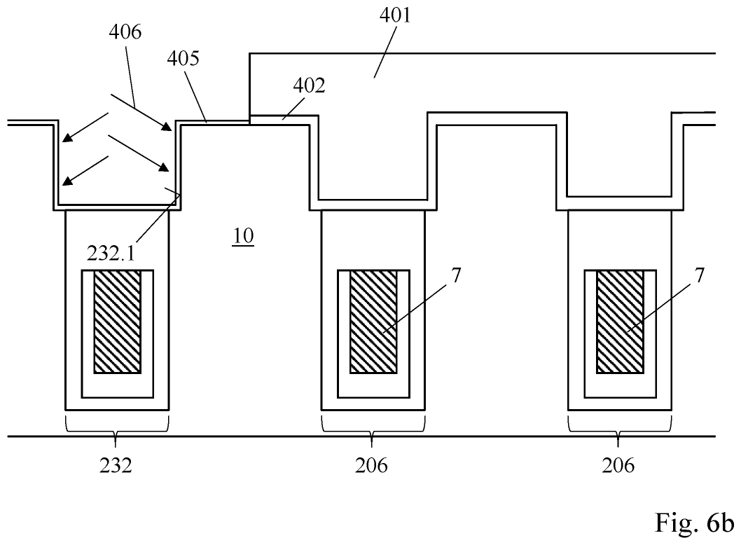

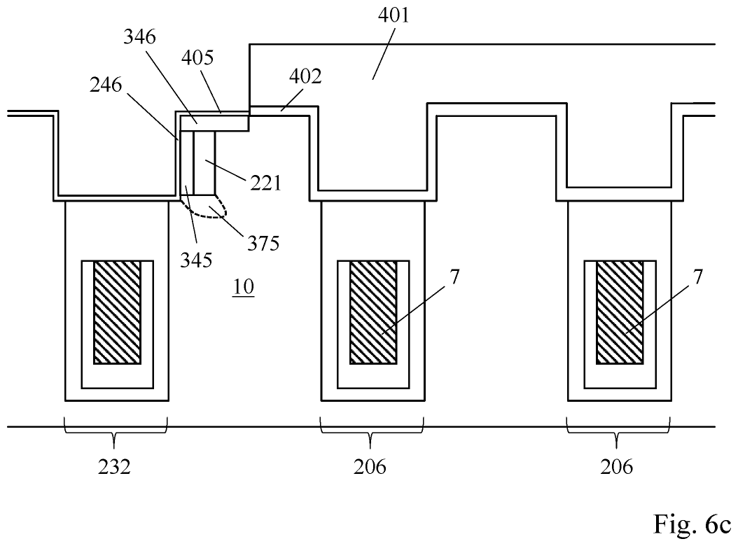

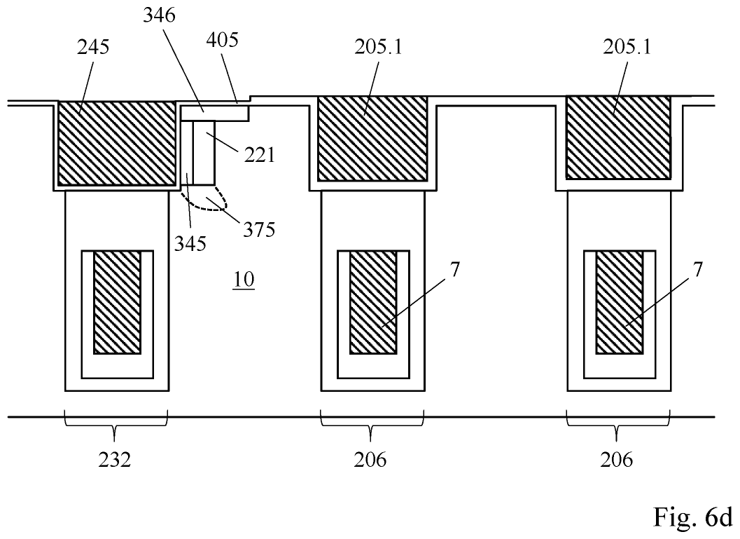

FIGS. 6a-d illustrate some manufacturing steps and further details of the lateral device. In FIG. 6a, the trench 232 has been etched and the shielding field electrode 31 has been formed in the lower portion thereof, simultaneously with etching the gate electrode trenches 206 for the vertical device and forming the field electrodes 7. These trenches 206 are covered by a mask 401, which protects an oxide layer 402 having been formed before and forming the gate dielectric 205.2 later on. The trench 232 is not covered by the mask 401, and the oxide has been removed there. As shown in FIG. 6a, the sidewalls 232.1 of the trench 232 are uncovered in its upper portion.

In FIG. 6b, a thin oxide layer 405 has been formed, and a dopant 406 is implanted obliquely through the sidewall 232.1 into the semiconductor body 10. As discussed in detail above, this allows for a formation of thin doped regions and layers laterally aside the trench 232. FIG. 6c shows the die after the implantation step, the body region 221 has been formed in the semiconductor body 10. Additionally, a thin counterdoping layer 345 has been formed between the body region 221 and the gate dielectric 264. It has an opposite conductivity type compared to the body region 221, namely p-type compared to n-type in this example. Furthermore, a surface channel blocker 346 has been formed at the frontside, having the same conductivity type as the body region 221 but a higher doping concentration. As a consequence of the oblique implantation, a residual doping region 375 is visible.

FIG. 6d illustrates a subsequent manufacturing step, the mask 401 has been removed, and the gate electrodes 205.1 of the vertical device 2 have been formed. Simultaneously, the lateral gate electrode 245 has been formed in the trench 232.

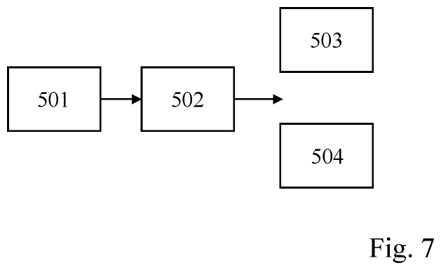

FIG. 7 summarizes some manufacturing steps in a flow diagram. After etching 501 and filling 502 the deep trench, the vertical transistor device can be formed 503, and the lateral transistor device can be formed 504, at least with some simultaneous process steps.

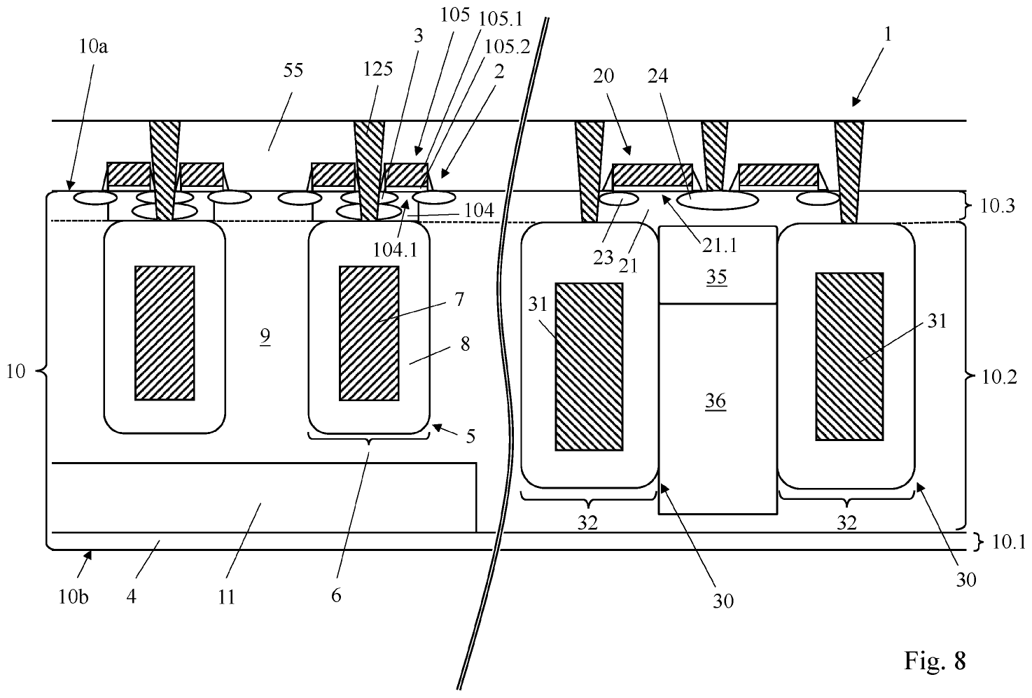

FIG. 8 illustrates a semiconductor die 1 with a vertical power transistor device 2. It has a source region 3 formed at a frontside 10a and a drain region 4 formed at a backside 10b of a semiconductor body 10. Though being a vertical device with the source and the drain region 3, 4 at opposite sides 10a, b, a channel region 104.1 formed in a body region 104 of the vertical power device 2 extends laterally. For an efficient area use, it is arranged vertically above a field electrode region 5 formed in a field electrode trench 6. The latter extends into a drift region 9 and comprises a field electrode 7 and a field dielectric 8.

On the frontside 10a of the semiconductor body 10, an insulating layer 55 is arranged, e. g. a silicon oxide layer. It is intersected by a contact 125 of the vertical device 2, which is arranged vertically above the field electrode 7. The contact 125 electrically connects the source region 3 to a frontside metallization (not shown). On the frontside 10a, covered by the insulating layer 55, a gate region 105 is arranged, it comprises a gate electrode 105.1 and a gate dielectric 105.2.

In addition to the vertical device 2, a lateral device 20 is formed in the die 1. It has a body region 21 with a lateral channel region 21.1, as well as a source and a drain region 23, 24. Due to the lateral design, the source and the drain region 23, 24 are both arranged at the frontside 10a of the semiconductor body 10. They are formed in an upper epitaxial layer 10.3, in which also the source region 3 and body region 104 of the vertical device 2 are arranged.

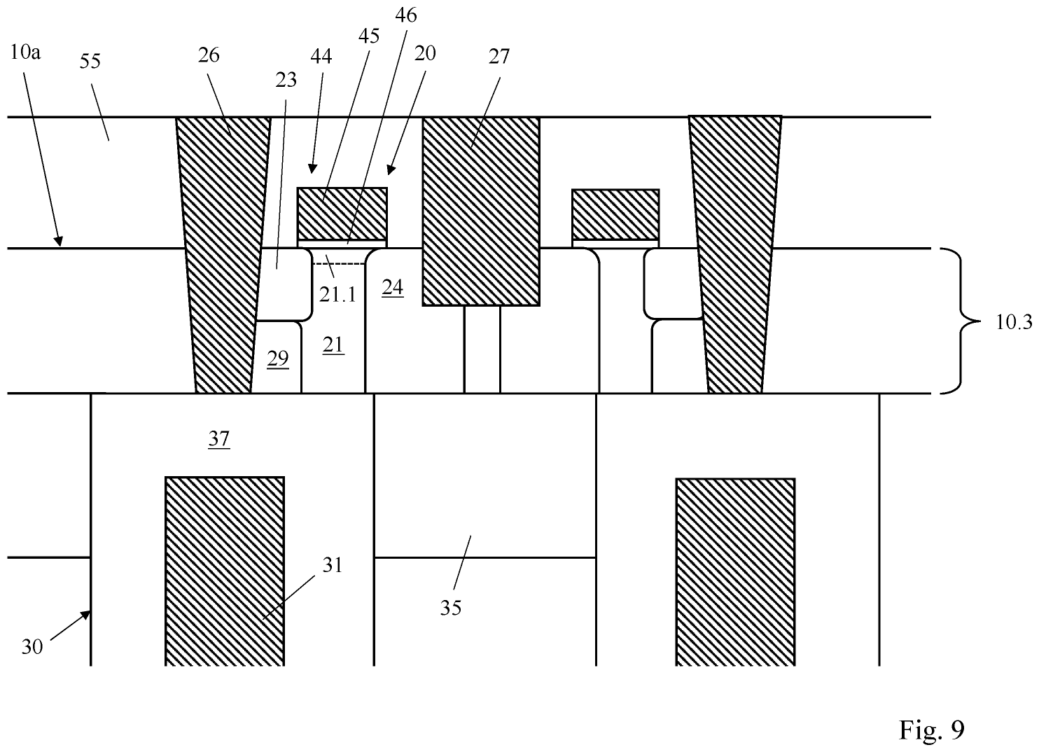

Below the lateral device 20, in a lower semiconductor body 10.1, 10.2, in particular in a lower epitaxial layer 10.2, a shielding field electrode region 30 with a shielding field electrode 31 is formed in a shielding field electrode trench 32. The shielding field electrode or electrodes 31 shield the lateral device 20 with respect to the backside 10b, namely with respect to the backside drain potential, which can enable a common drain backside. The shielding field electrodes 31 can be contacted outside the sectional plane shown, e. g. outside the cell of the lateral device. Between the shielding field electrode trenches 32, a well region 35 is arranged, which is electrically connected to the vertical power FET source, see in detail FIG. 9. In addition, an additional implant region 36 can be formed below the well region to optimize the breakdown voltage.

The shielding field electrode trenches 32 have a larger lateral width than the field electrode trenches 6 of the vertical device 2. In consequence, since these trenches 6, 32 are in particular etched simultaneously, the shielding field electrode trenches 32 can extend deeper into the semiconductor body 10, in particular the lower epitaxial layer 10.2. To shorten a vertical current path in the drift region 9 of the vertical device 2, a bridge implant region 11 is formed below its field electrode trenches 6, namely between the drift region 9 and the drain region 4. It is of the same conductivity type as the drift region 9, n-type in this example, but has a higher doping concentration.

FIG. 9 illustrates a first design of the lateral device 20 integrated into the die 1 in a detailed view. Above the body region 21 with the channel region 21.1 formed between the source and drain region 23, 24, a lateral gate region 44 of the device 20 is arranged, comprising a lateral gate electrode 45 and a lateral gate dielectric 46. The gate region 44 is covered by the insulating layer 55 formed on the frontside 10a of the semiconductor body 10. The insulating layer 55 is intersected by a source contact 26 connecting the source region 23 to a metallization layer above (not shown). In addition, the source contact 26 contacts the body region 21 via a highly doped body contact region 29. In the example shown, the contact 26 extends through the upper epitaxial layer 10.3 and ends on an insulating spacer 37 formed in the shielding field electrode trench 30 above the shielding field electrode 31. Alternatively, it can end above, e. g. inside the body contact region 29.

The drain region 24 is contacted via a drain contact 27 extending through the insulating layer 55 and into the upper epitaxial layer 10.3. In the example shown, the source contact 26 is arranged vertically above the shielding field electrode 31, and the drain contact 27 is arranged on a lateral position between the shielding field electrode trenches 32. The device 20 is a p-MOS in this example, the source and the drain region 23,24 being p-doped and the body region 21 being n-doped. The region centrally below the drain contact 27, which is not referenced with a numeral, is a residuum from manufacturing, namely of a stop island made for instance of silicon nitride and used when planarizing the upper epitaxial layer 10.3. Alternatively, it could be removed completely, the drain region 24 extending laterally over the whole distance below the drain contact 27.

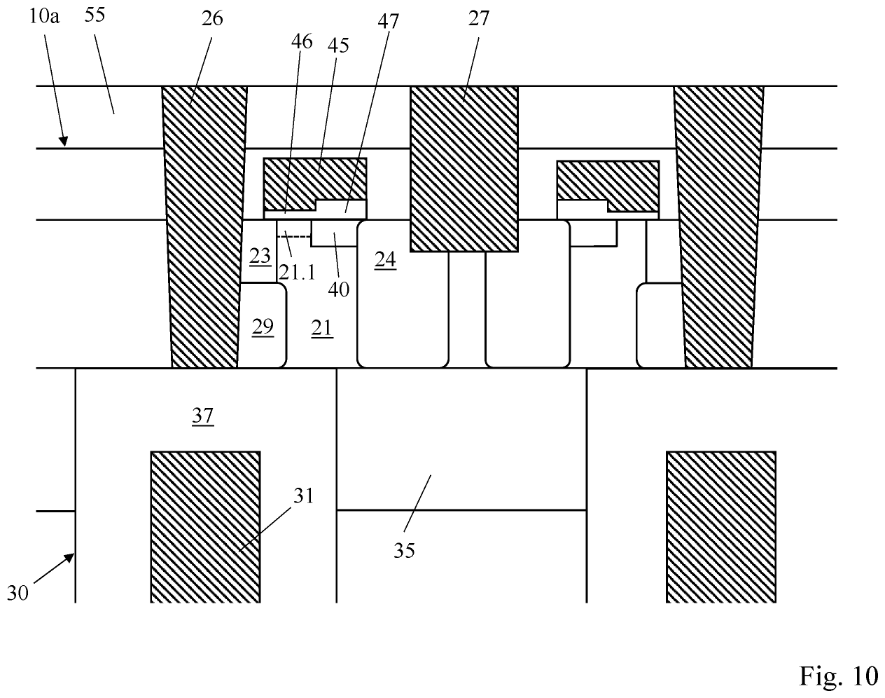

FIG. 10 illustrates an alternative design of the lateral device 20. Generally, in this disclosure, the same reference numerals are used for the same features or features having the same function, and reference is made to the respectively other figures. The device 20 of FIG. 10 differs from FIG. 9 in that it comprises additionally a lateral drift region 40 formed between the drain region 24 and the channel region 21.1. Like the source and the drain region 23,24 the drift region 40 is p-doped but with a lower doping concentration. In this example, no separate field electrode is provided, instead the lateral gate electrode 45 capacitively couples to the lateral drift region 40. Therein, a lateral field dielectric 47 is thicker than the lateral gate dielectric 46.

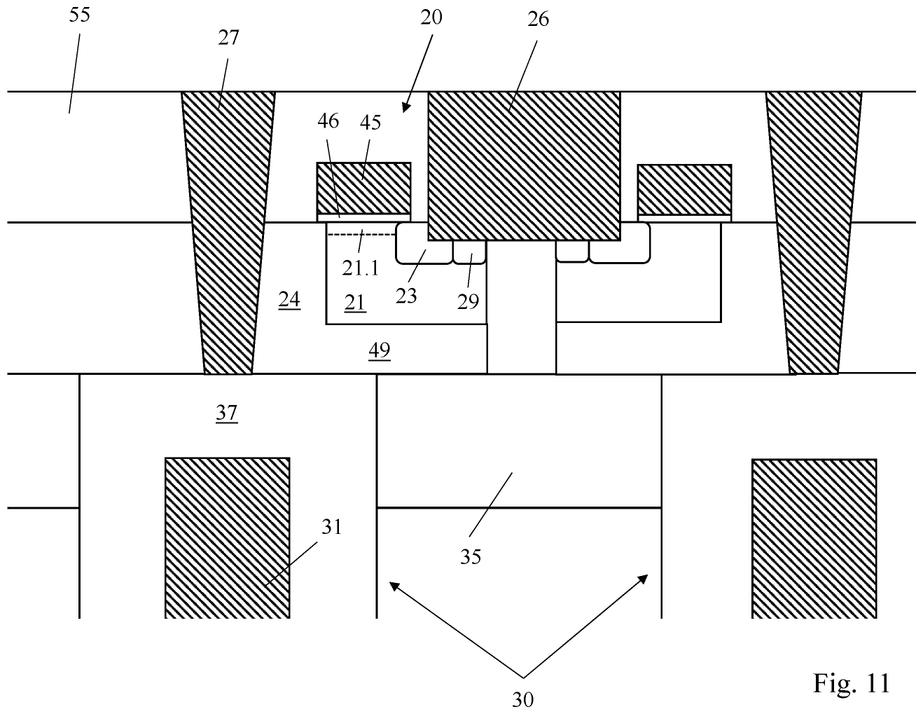

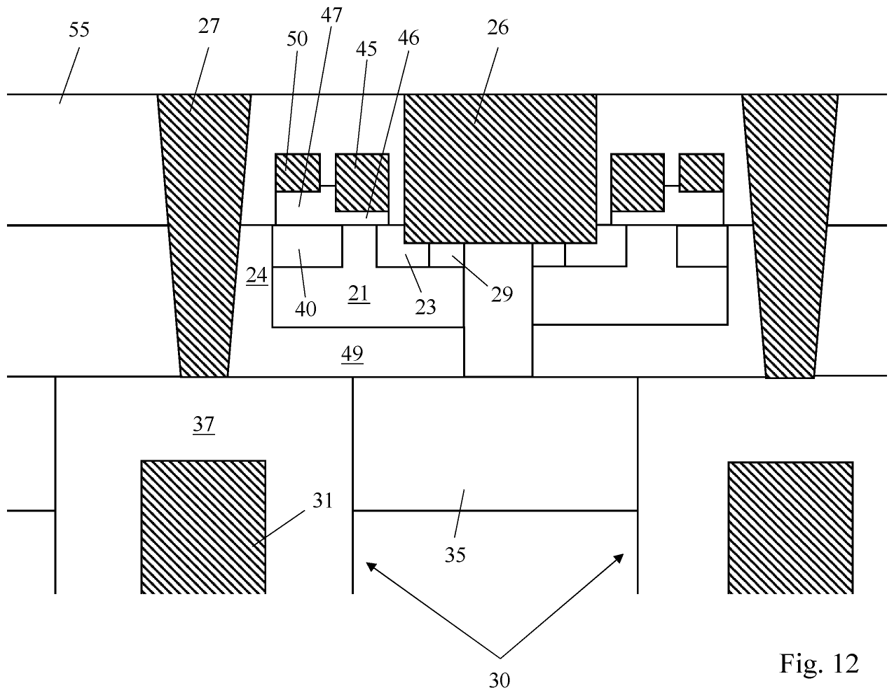

In the device 20 of FIG. 11, in contrast to FIGS. 9 and 10, the source region 23 and the source contact 26 are arranged laterally between the trenches 30, and the drain region 24 with the drain contact 27 is arranged vertically above the shielding field electrode 31. Like in FIGS. 9 and 10, the well region 35 is connected to the drain region 24, a lateral implant region 49 being provided for that purpose. It is p-doped, like the source and the drain region 23, 24 and the well region 35. In the design of FIG. 11, the highly doped body contact region 29 is arranged below the source contact 26.

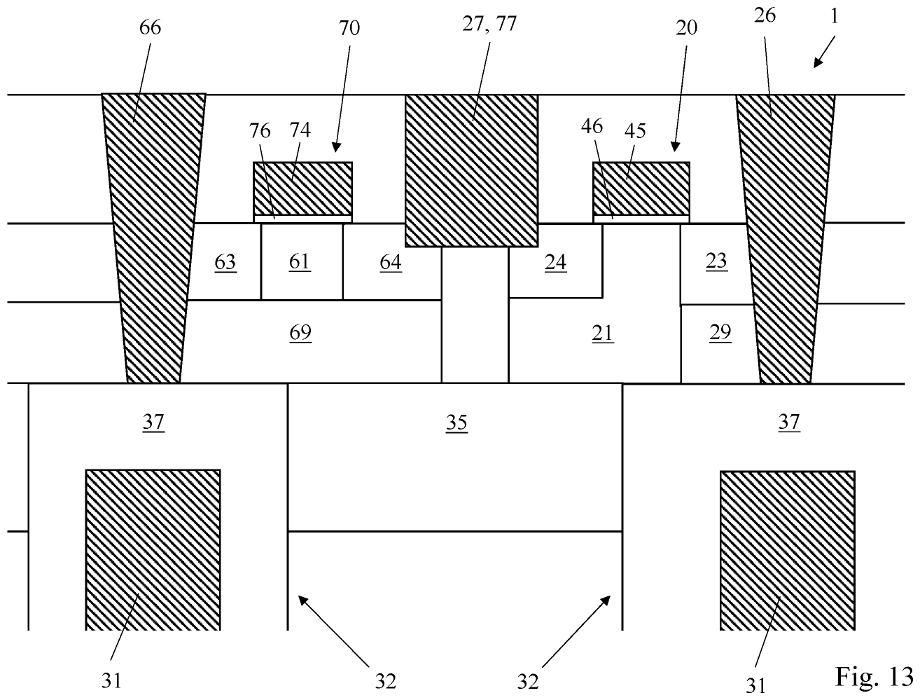

The device 20 of FIG. 12 differs from FIG. 11 in that it comprises in addition a lateral drift region 40, which is p-doped like the drain region 24 but with a lower doping concentration. Above the lateral drift region 40, a lateral field electrode 50 is formed, coupling via a lateral field dielectric 47 which is thicker than the lateral gate dielectric 46. The lateral field electrode 50 is electrically isolated from the lateral gate electrode 45, it can for instance be connected to source (outside the drawing plane) or operated separately.

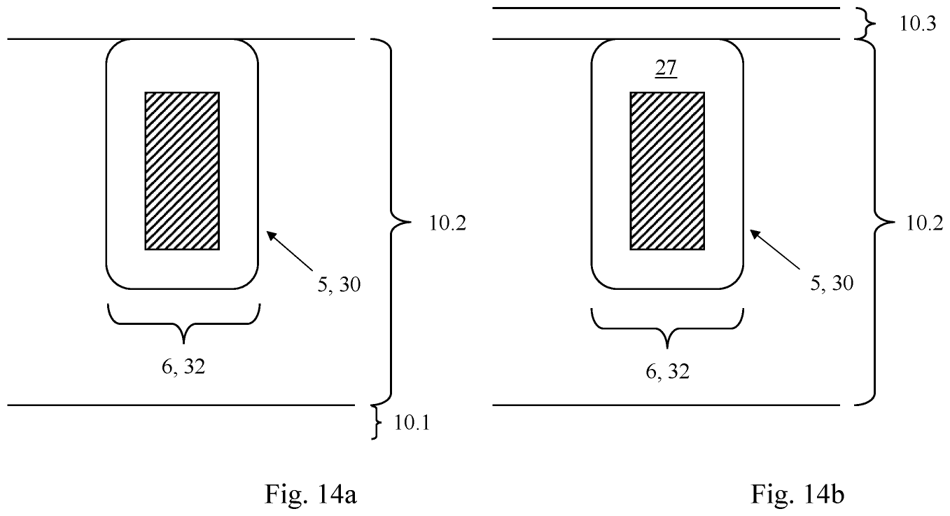

FIG. 13 illustrates an additional lateral transistor device 70 formed together with the (first) lateral transistor device 20 and the vertical power device (not shown) in the die 1. Regarding the design of the first lateral transistor device 20, reference is made to FIG. 9. It is a p-MOS, the source and drain region 23, 24 being p-doped and the body region 21 n-doped. The additional transistor device 70 is an n-MOS, its source region 63 being n-doped like the drain region 64, and the body region 61 being p-doped. A source contact 66 of the p-MOS is formed above the shielding field electrode 31, it additionally contacts a highly p-doped body contact region 69.

The source contact 26 of the p-MOS is formed above the neighbouring field electrode 31, its drain contact 27 is formed on a lateral position between the trenches 32. This contact serves also as a drain contact 77 of the n-MOS, the devices 20, 70 are connected as a CMOS structure, forming in particular an inverter. A gate electrode 74 of the n-MOS capacitively coupling via a gate dielectric 76 is electrically connected to the gate electrode 45 outside the drawing plane or in a metallization layer above (not shown).

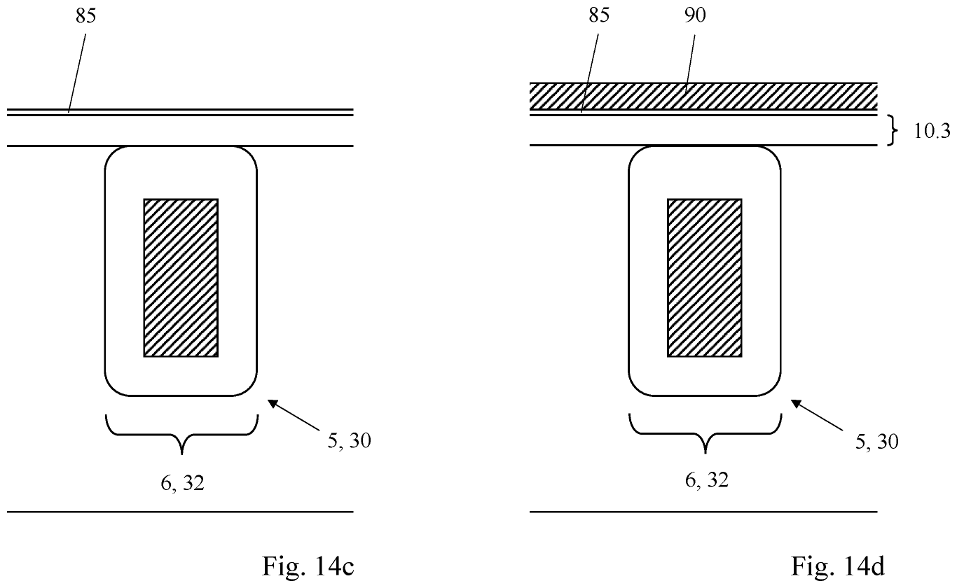

FIGS. 14a-d illustrate some manufacturing steps that can apply for both, the vertical and the lateral device. In FIG. 14a, the respective trench 6, 32 has been etched into the lower epitaxial layer 10.2, and the respective field electrode region 5, 30 has been formed. Then, the upper epitaxial layer 10.3 is deposited, covering the respective trench 6, 32, see FIG. 14b. Subsequently, a dielectric layer 85 is deposited (FIG. 14c), followed by a deposition of an electrically conductive layer 90. By structuring the latter, e. g. prior to the deposition by a mask or in a subsequent etch back step, the gate electrode or electrodes can be defined. The dielectric layer 85 defines the gate dielectric, it can be removed from other locations of the die in an etch back step after the gate electrode formation. Implantations forming the different regions in the upper epitaxial layer 10.3 can be performed in between steps 14b and c and/or after the gate electrode formation. The upper epitaxial layer 10.3 can be doped in situ or in particular after its deposition to form the regions required for the respective device.

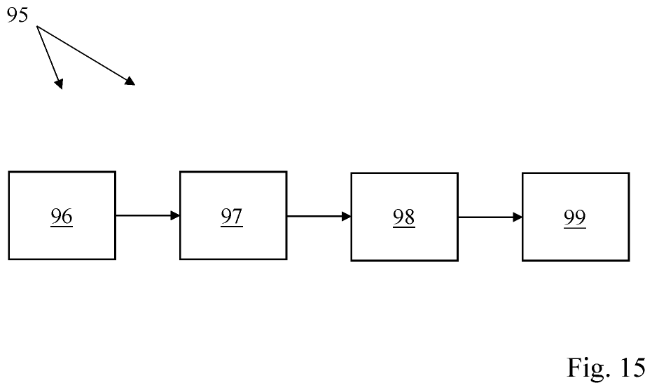

FIG. 15 shows a flow diagram illustrating some manufacturing steps 95. After etching 96 the shielding field electrode trench, the shielding field electrode region is formed 97. Subsequently, the well region can be formed 98, prior to forming 99 the lateral transistor device above.

1-15. (canceled)

16. A semiconductor die, comprising:
a vertical power transistor device having a source region and a drain region at opposite sides of a semiconductor body;
a lateral transistor device having a body region with a lateral channel region, and a source region and a drain region formed at a frontside of the semiconductor body; and
a deep trench arranged laterally between the vertical power transistor device and the lateral transistor device,
wherein the deep trench forms a deep trench isolation.

17. The semiconductor die of claim 16, further comprising:
a shielding field electrode region with a shielding field electrode formed in a shielding field electrode trench in the semiconductor body,
wherein at least a portion of the lateral transistor device is arranged vertically above the shielding field electrode region.

18. The semiconductor die of claim 17, the vertical power transistor device comprises a field electrode region with a field electrode formed in a field electrode trench, and wherein the field electrode trench of the vertical power transistor device and the shielding field electrode trench differ from each other in at least one of vertical depth and lateral width.

19. The semiconductor die of claim 17, wherein a contact region of the shielding field electrode extends laterally aside the channel region of the lateral device and vertically up to the frontside of the semiconductor body.

20. The semiconductor die of claim 17, wherein a gate electrode of the lateral transistor device is arranged in a trench laterally aside the channel region of the lateral transistor device.

21. The semiconductor die of claim 20, wherein the gate electrode of the lateral transistor device is arranged above the shielding field electrode in the shielding field electrode trench.

22. The semiconductor die of claim 20, further comprising:
a counterdoping layer disposed laterally between the body region and a gate dielectric of the lateral transistor device,
wherein the counterdoping layer is made of an opposite conductivity type compared to the body region of the lateral transistor device.

23. The semiconductor die of claim 20, wherein the lateral channel region is offset downwards into the semiconductor body.

24. The semiconductor die of claim 23, further comprising:
a surface channel blocker region, which is made of a same conductivity type as the body region of the lateral transistor device but with a higher doping concentration, formed above the body region of the lateral transistor device.

25. The semiconductor die of claim 20, wherein a lateral field electrode of the lateral transistor device is arranged aside the drift region of the lateral transistor device with respect to a first lateral direction, and aside the gate electrode of the lateral transistor device with respect to a second lateral direction, in the same trench with the gate electrode.

26. The semiconductor die of claim 16, wherein the source region and/or the drain region of the lateral transistor device comprises a surface implant with a higher doping concentration compared to a body region of the vertical power transistor device.

27. The semiconductor die of claim 16, further comprising:
a source contact electrically contacting the source region of the lateral transistor device and vertically extending through the source region down into the body region of the lateral transistor device,
wherein the source contact forms a body contact.

28. The semiconductor die of claim 16, wherein a gate electrode of the lateral transistor device is arranged in a trench laterally aside the channel region of the lateral transistor device.

29. The semiconductor die of claim 16, wherein the lateral transistor device comprises a lateral drift region which is arranged laterally between the lateral channel region and the drain region of the lateral transistor device, and wherein the drift region is made of a same conductivity type as the drain region but with a lower doping concentration.

30. A method of manufacturing a semiconductor die, the method comprising:
forming a vertical power transistor device having a source region and a drain region at opposite sides of a semiconductor body;
forming a lateral transistor device having a body region with a lateral channel region, and a source region and a drain region formed at a frontside of the semiconductor body;
etching a deep trench laterally between the vertical power transistor device and the lateral transistor device; and
filling the deep trench to form a deep trench isolation.

31. The method of claim 30, wherein forming the lateral transistor device comprises:
implanting a dopant obliquely via a sidewall of the deep trench into the semiconductor body to form the body region of the lateral transistor device.

32. A semiconductor device, comprising:
a semiconductor body;
a first transistor device having a source region and a drain region at opposite sides of the semiconductor body, the first transistor device being a vertical power transistor device;
a second transistor device having a source region and a drain region formed at a frontside of the semiconductor body; and
a deep trench arranged laterally between the first transistor device and the second transistor device, wherein the deep trench forms a deep trench isolation.

33. The semiconductor device of claim 32, wherein the first transistor device comprises a plurality of first trenches, each of the first trenches having a field plate and a gate electrode formed therein.

34. The semiconductor device of claim 33, wherein the second transistor device comprises a plurality of second trenches, each of the second trenches having a field plate and a gate electrode formed therein.

35. The semiconductor device of claim 34, wherein the plurality of first trenches and the plurality of second trenches extend from the frontside of the semiconductor body along a first direction into the semiconductor body, and wherein the plurality of first trenches and the plurality of second trenches have a same depth.

36. The semiconductor device of claim 34, wherein upper surfaces of the field plates within the plurality of first trenches and upper surfaces of the field plates within the plurality of second trenches are horizontally aligned.

37. The semiconductor device of claim 36, wherein lower surfaces of the field plates within the plurality of first trenches and lower surfaces of the field plates within the plurality of second trenches are horizontally aligned.

38. The semiconductor device of claim 37, wherein a width of the field plates within the plurality of first trenches and a width of the field plates within the plurality of second trenches is the same.

39. The semiconductor device of claim 36, wherein a lower surface of the gate electrodes within the plurality of first trenches and a lower surface of the gate electrodes within the plurality of second trenches are horizontally aligned.

40. The semiconductor device of claim 39, wherein a width of the gate electrodes within the plurality of first trenches and a width of the gate electrodes within the plurality of second trenches is the same.

41. The semiconductor device of claim 40, wherein a height of the gate electrodes within the plurality of first trenches and a height of the gate electrodes within the plurality of second trenches is the same.
